(19) United States
(12) Patent Application Publication
(10) Pub. No.: US 2022/0231097 A1
(43) Pub. Date: Jul. 21, 2022

(54) DISPLAY SCREEN, METHOD FOR MANUFACTURING SAME AND DISPLAY TERMINAL

(71) Applicants: Chengdu BOE Optoelectronics Technology Co., Ltd., Chengdu (CN); BOE Technology Group Co., Ltd., Beijing (CN)

(72) Inventors: Zuojia WANG, Beijing (CN); Liqiang CHEN, Beijing (CN); Wei WANG, Beijing (CN)

(21) Appl. No.: 17/546,932

(22) Filed: Dec. 9, 2021

(30) Foreign Application Priority Data
Jan. 19, 2021 (CN) 202110068370.9

(51) Int. Cl. H01L 27/32; H01L 51/00; H01L 51/56; H01Q 1/22; H01Q 7/00

(52) U.S. Cl. CPC H01L 27/3225; H01L 27/323; H01L 27/3262; H01L 27/3265; H01L 2251/5338; H01L 51/0097; H01L 51/56; H01Q 1/22; H01Q 7/00; H01L 27/3276

(57) ABSTRACT

Disclosed are a display screen, a method for manufacturing the same, and a display terminal. The display screen includes a display region and a non-display region surrounding the display region; wherein the display region includes a plurality of sub-pixels, at least one of the plurality of sub-pixels including a pixel circuit and a light-emitting element, the pixel circuit being configured to drive the light-emitting element and includes at least one metal layer; and the non-display region includes at least one antenna disposed in the same layer as one of the at least one metal layer.

### CROSS-REFERENCE TO RELATED APPLICATION

The present disclosure claims priority to the Chinese patent application No. 202110068370.9, filed on Jan. 19, 2021 and entitled “DISPLAY SCREEN, METHOD FOR MANUFACTURING SAME AND DISPLAY TERMINAL,” the disclosure of which is incorporated herein by reference in its entirety.

### TECHNICAL FIELD

The present disclosure relates to the field of display technologies, and in particular relates to a display screen, a method for manufacturing the same, and a display terminal.

### BACKGROUND

With the advancement of the flexible display screen industry and the continuous innovation of its application, surrounding-screen display products have been developed. In the surrounding-screen display product, a flexible display screen surrounds the front side, the side surfaces and the back side of a display terminal in a large proportion, such that more information is displayed in a larger area of the display product.

### SUMMARY

Embodiments of the present disclosure provide a display screen, a method for manufacturing the same, and a display terminal.

In one aspect of the embodiments of the present disclosure, a display screen is provided. The display screen includes a display region and a non-display region surrounding the display region; wherein the display region includes a plurality of sub-pixels, at least one of the plurality of sub-pixels including a pixel circuit and a light-emitting element, and the pixel circuit being configured to drive the light-emitting element and includes at least one metal layer; and the non-display region includes at least one antenna disposed in the same layer as one of the at least one metal layer.

In some embodiments, the pixel circuit includes: a drive transistor including an active layer, a gate, a source, and a drain, wherein the gate is disposed on a side of the active layer and is insulated from the active layer, and both of the source and the drain are disposed on a side, distal from the active layer, of the gate and are connected to the active layer; and a storage capacitor including a first electrode plate and a second electrode plate, wherein the second electrode is disposed on a side, distal from the active layer, of the first electrode plate, wherein the at least one antenna is disposed in the same layer as one of the gate, the source, the drain, the first electrode plate, and the second electrode plate.

In some embodiments, one of the first electrode plate and the second electrode plate is disposed in the same layer as the gate.

In some embodiments, one of the first electrode plate and the second electrode plate is disposed in the same layer as the source.

In some embodiments, the non-display region further includes a take-up circuit region, a first bonding region and a first flexible circuit board, wherein the first bonding region is disposed on a side, distal from the display region, of the take-up circuit region, the first flexible circuit board is bonded to the first bonding region, and a screen driving integrated circuit is bonded to the first flexible circuit board.

In some embodiments, an antenna integrated circuit is further bonded to the first flexible circuit board, wherein the at least one antenna is connected to the antenna integrated circuit by wiring and the first bonding region in the non-display region sequentially.

In some embodiments, the display screen further includes at least one second flexible circuit board, wherein the second flexible circuit board is bonded to the at least one antenna, and an antenna integrated circuit is bonded to the second flexible circuit board.

In some embodiments, each of the first flexible circuit board and the second flexible circuit board includes a flexible portion and an inflexible portion, and a width B of the flexible portion, a bonding width L of the flexible portion, a width C of the inflexible portion, and a bending radius R of the flexible portion meet: B−C≥L+πR.

In some embodiments, the display screen is a flexible display screen and includes a first side, a second side, a third side, and a fourth side that are successively connected; wherein the second side and the fourth side are curved; the first bonding region is disposed on the third side; and the antenna is disposed on at least one of: the first side; or the third side.

In some embodiments, two antennas are configured and are both disposed on the third side, wherein the first bonding region is disposed between the two antennas.

In some embodiments, two antennas are configured and are both disposed on the first side, wherein one of the antennas is proximal to the second side, and the other of the antennas is proximal to the fourth side.

In some embodiments, the at least one antenna includes an annular coiled antenna or a rectangular coiled antenna.

In some embodiments, the display screen is a touch display screen, the screen driving integrated circuit is a touch driving integrated circuit, and the non-display region further includes a display driving integrated circuit disposed between the take-up circuit region and the first flexible circuit board.

In another aspect of the embodiments of the present disclosure, a display terminal is provided. The display terminal includes a display screen, and the display screen includes a display region and a non-display region surrounding the display region, wherein the display region includes a plurality of sub-pixels, at least one of the plurality of sub-pixels includes a pixel circuit and a light-emitting element, the pixel circuit being configured to drive the light-emitting element and including at least one metal layer; and the non-display region includes at least one antenna disposed in the same layer as one of the at least one metal layer.

In some embodiments, the display terminal is a surrounding-screen display terminal; wherein the display screen is a flexible display screen, is curved around and includes a first side, a second side, a third side and a fourth side that are successively connected; wherein the second side and the fourth side are bent to be U-shaped.

In some embodiments, the surrounding-screen display terminal further includes a supporting rear housing disposed between the first side and the third side.

In some embodiments, the non-display region further includes a take-up circuit region, a first bonding region and a first flexible circuit board; wherein the first bonding region is disposed on a side, distal from the display region, of the take-up circuit region, and the first flexible circuit board is bonded to the first bonding region, a screen driving integrated circuit is bonded to the first flexible circuit board.

In some embodiments, at least one antenna is disposed on the first side: a first bonding region is disposed on the third side; the at least one antenna is disposed on a back side of the surrounding-screen display terminal; and a take-up circuit region, the first bonding region and a first flexible circuit board are disposed on a front side of the surrounding-screen display terminal and are folded on a back side of the display screen.

In some embodiments, both of the at least one antenna and a first bonding region are disposed on the third side, and the at least one antenna, a take-up circuit region, the first bonding region and a first flexible circuit board are disposed on a front side of the surrounding-screen display terminal and are folded on a back side of the display screen; and

a metal part of the surrounding-screen display terminal opposite to the at least one antenna is provided with a signal through hole.

In yet another aspect of the embodiments of the present disclosure, a method for manufacturing a display screen is provided. The display screen includes a display region and a non-display region surrounding the display region. The method includes: providing a base substrate; and forming a plurality of sub-pixels and at least one antenna on the base substrate; wherein the plurality of sub-pixels are provided in the display region; the at least one antenna is disposed in the non-display region; at least one of the plurality of sub-pixels includes a pixel circuit and a light-emitting element, the pixel circuit being configured to drive the light-emitting element and including at least one metal layer; and the at least one antenna is manufactured in the same layer as one of the at least one metal layer.

### BRIEF DESCRIPTION OF THE DRAWINGS

FIG. 1a is a front view of a display screen (using a rectangular coiled antenna) according to an embodiment of the present disclosure;

FIG. 1b is a schematic sectional view of a sub-pixel of a display screen according to an embodiment of the present disclosure;

FIG. 1c is a side view of a surrounding-screen display terminal according to an embodiment of the present disclosure;

FIG. 1d is a front view of a display screen (using a circular coiled antenna) according to an embodiment of the present disclosure;

FIG. 2a is a front view of a display screen according to an embodiment of the present disclosure:

FIG. 2b is a side view of a surrounding-screen display terminal according to an embodiment of the present disclosure;

FIG. 3a is a front view of a display screen according to an embodiment of the present disclosure;

FIG. 3b is a side view of a surrounding-screen display terminal according to an embodiment of the present disclosure;

FIG. 4a is a front view of a display screen according to an embodiment of the present disclosure:

FIG. 4b is a side view of a surrounding-screen display terminal according to an embodiment of the present disclosure:

FIG. 5 is a schematic view showing folding of a first flexible circuit board or a second flexible circuit board according to an embodiment of the present disclosure; and

FIG. 6 is a flowchart of a method for manufacturing a display screen according to an embodiment of the present disclosure.

### DETAILED DESCRIPTION

The technical solutions in the embodiments of the present disclosure will be clearly and completely described below with reference to the accompanying drawings in the embodiments of the present disclosure. Apparently, the described embodiments are only part but not all of the embodiments of the present disclosure. All other embodiments obtained by those of ordinary skill in the art without creative efforts based on the embodiments in the present disclosure shall fall within the protection scope of the present disclosure.

A surrounding-screen display terminal, e.g., a surrounding-screen mobile phone, has an excessively large screen-to-body ratio design that occupies most area of the display terminal, which makes it more difficult to assemble internal components of the mobile phone. With the vigorous promotion of 5G technologies, a multi-antenna design makes the installation of an antenna module more complicated. For some surrounding-screen mobile phones in the related art, it is necessary to insert their antenna modules from surrounding openings of the surrounding screens during installation, of which the operation space is extremely limited. As a result, the assembling difficulty is improved and it is hard to ensure the assembling accuracy.

In order to solve the above technical problem, embodiments of the present disclosure provide a display screen and a display terminal. An antenna of the display terminal is reasonably arranged to reduce the assembling difficulty and the manufacturing cost of the whole device.

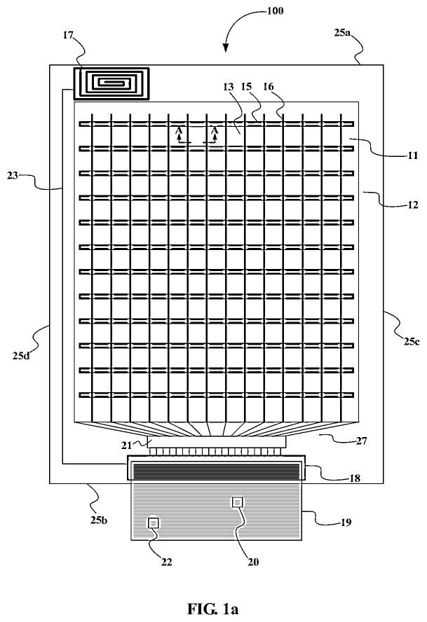

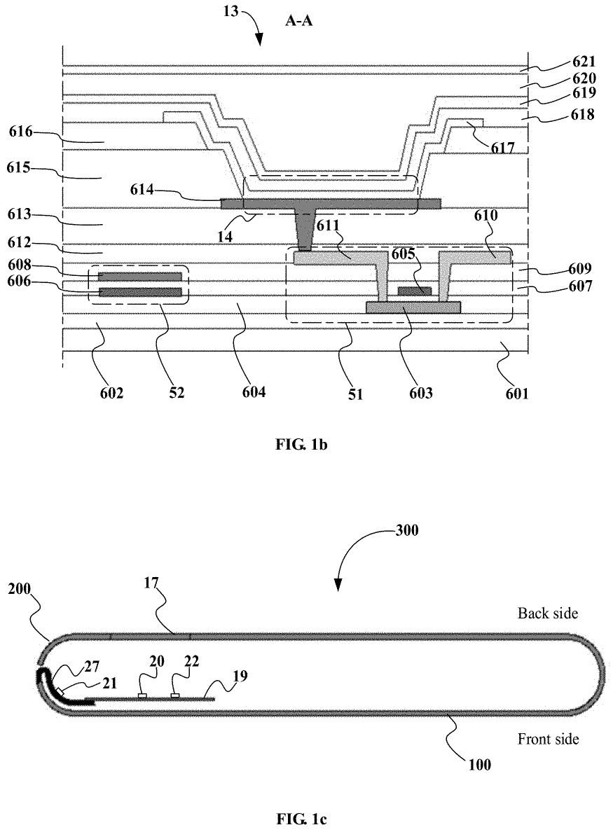

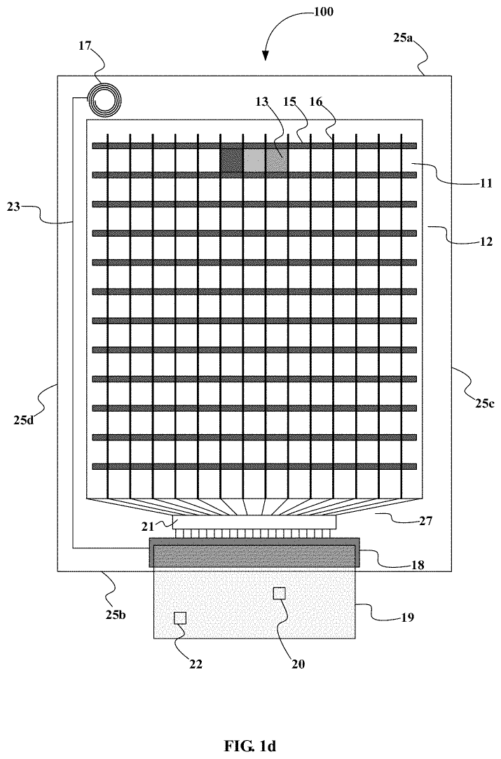

An embodiment of the present disclosure provides a display screen. The display screen may be an OLED display screen. As shown in FIGS. 1a and l b, the display screen 100 includes a display region 11 and a non-display region 12 surrounding the display region 11. The display region includes a plurality of sub-pixels 13, and at least one of the plurality of sub-pixels 13 includes a pixel circuit and a light-emitting element 14. For example, the light-emitting element 14 is an organic light-emitting diode (OLED). The pixel circuit is configured to drive the light-emitting element 14, for example, to be turned on or off, and to adjust the luminance of the light-emitting element 14.

The pixel circuit includes at least one metal layer. At least one antenna 17 is provided in the non-display region 12 and is disposed in the same layer as one of the at least one metal layer. The same layer in the embodiments of the present disclosure can be understood as being made of the same layer or several layers of materials, or being manufactured in the same patterning process, or being disposed on the same surface of the same layer structure.

As shown in FIG. 1b, in some embodiments, the pixel circuit of the sub-pixel 13 includes a drive transistor 51 for driving the light-emitting element 14 and a storage capacitor 52.

The drive transistor 51 includes an active layer 603, agate 605, a source 610 and a drain 611. The gate 605 is disposed on a side of the active layer 603 and is insulated from the active layer 603. For example, the active layer 603 and the gate 605 are spaced apart, and a first insulating layer 604 is disposed between the active layer 603 and the gate 605. Both of the source 610 and the drain 611 are disposed on a side, distal from the active layer 603, of the gate 605, and are connected to the active laver 603. The source 610 and the drain 611 are disposed in the same layer.

The storage capacitor 52 includes a first electrode plate 606 and a second electrode plate 608. The first electrode plate 606 abuts against the second electrode plate 608, and the second electrode plate 608 is disposed on a side, distal from the active layer 603, of the first electrode plate 606 and is insulated from the first electrode plate 606. For example, the first electrode plate 606 and the second electrode plate 608 are spaced apart, and a second insulating layer 607 is disposed between the first electrode plate 606 and the second electrode plate 608.

The at least one antenna 17 may be disposed in the same layer as the gate 605, or the source 610 and the drain 611, or the first electrode plate 606 or the second electrode plate 608.

As an example, in some embodiments, the first electrode plate 606 is disposed in the same layer as the gate 605. In other examples, the second electrode plate 608 is disposed in the same layer as the gate 605.

In addition, in some embodiments, one of the first electrode plate 606 and the second electrode plate 608 may be disposed in the same layer as the source 610. For example, the second electrode plate 608 is disposed in the same layer as the source 610; or, the first electrode plate 606 is disposed in the same layer as the gate 605, and the second electrode plate 608 is disposed in the same layer as the source 610.

Referring to FIG. 1b, as illustrated by a cross section of the sub-pixel 13 A-A, the sub-pixel 13 includes a base substrate 601, a buffer layer 602, an active layer 603, a first insulating layer 604, a gate 605, a second insulating layer 607, a second electrode plate 608, a third insulating layer 609, a source 610, a passivation layer 612, a planarization layer 613, an anode layer 614, a pixel defining layer 615, a spacer layer 616, an organic light-emitting layer 617, a cathode layer 618, a first inorganic encapsulation layer 619, an organic encapsulation layer 620, and a second inorganic encapsulation layer 621 that are disposed on a side of the base substrate 601 and are sequentially disposed in a direction distal going away from the base substrate 601; and the sub-pixel 13 further includes a first electrode plate 606 disposed in the same layer as the gate 605 and a drain 611 disposed in the same layer as the source 610.

The source 610 and the drain 611 are connected to the active layer 603 through via holes, and the anode layer 614 is connected to the drain 611 through a via hole. In the display region 11, a gate line 15 (referring to FIG. 1a) for transmitting a signal to the gate 603 may be disposed in the same layer as the gate 605, and a data line 16 (referring to FIG. 1a) for transmitting a signal to the source 610 may be disposed in the same layer as the source 610 and the drain 611.

In some embodiments, the display screen may be a bendable flexible display screen or an inflexible flat display screen. The following description takes the display screen as a bendable flexible display screen as an example.

The specific shape of the display screen 100 is not limited. As shown in FIG. 1a and FIG. 1c, in some embodiments, the display screen 100 is a flexible display screen applied to a surrounding-screen display terminal. The display screen 100 includes a first side 25a, a second side 25c, a third side 25b and a fourth side 25d that are successively connected, wherein the second side 25c and the fourth side 25d are curved, for example, substantially bent to be C-shaped, and the display screen 100 is substantially rectangular when flattened out. In some other embodiments, the display screen 100 substantially may also be in a parallelogram shape or other special shapes when flattened out.

In some embodiments, as shown in FIG. 1a, the non-display region 12 further includes a take-up circuit region 27, a first bonding region 18 disposed on a side, distal from the display region 11, of the take-up circuit region 27, and a first flexible circuit board 19 bonded to the first bonding region 18. The first flexible circuit board 19 is bonded to a screen driving integrated circuit 20, i.e., a screen driving IC 20.

The display screen 100 may only have a display function, and the screen driving IC is a display driving IC that controls the display region to achieve the display function. The display screen 100 may also have both a display function and a touch function. For example, in an embodiment, the display screen 100 is a touch display screen with both display and touch functions, and the screen driving IC 20 is a touch driving IC that controls the display region 11 to achieve the touch function. Accordingly, the non-display region 12 may further include a display driving IC 21 disposed between the take-up circuit region 27 and the first flexible circuit board 19. That is, the display driving IC 21 is bonded to a line between the flexible take-up circuit region 27 and the flexible first bonding region 18. For example, the display driving IC 21 is bonded to the line between the take-up circuit region 27 and the first bonding region 18 by using the chip-on-PI (COP) encapsulation technology, such that the display driving IC 21 may be bent backward with a screen thereby further reducing the frame of the display terminal and achieving an approximately “borderless” effect.

In some embodiments, both of the display driving IC and the touch driving IC may be bonded to the first flexible circuit board 19 to achieve the display function and the touch function of the display region.

In some embodiments, a specific shape of the antenna 17 is not limited. For example, the antenna 17 may be a rectangular coiled antenna as shown in FIG. 1a or an annular coiled antenna as shown in FIG. 1d. In addition, the antenna 17 may also be designed in other shapes, e.g., an elliptical coiled shape.

In some embodiments, the display screen 100 is a touch display screen and the screen driving IC 20 is a touch driving IC. As shown in FIGS. 1a and 1c, the non-display region 12 further includes a display driving IC 21 disposed between the take-up circuit region 27 and the first flexible circuit board 19; and in addition to the touch driving IC (the screen driving IC 20), an antenna IC 22 is bonded to the first flexible circuit board 19. At least one antenna 17 is connected to the antenna IC 22 by wiring and the first bonding region 18 in the non-display region 12 sequentially.

The non-display region 12 includes an edge wiring region 23 for wiring. As an example, only part of the wiring is shown in the figure. The wiring of the edge wiring region 23 is used for transmitting a signal between the display region 11 and the first bonding region 18, such as a display signal and/or a touch signal. The wiring of the edge wiring region 23 may also include anti-static wiring, etc.

In some embodiments, some wiring of the edge wiring region 23 is also configured to electrically connect the antenna 17 to the first bonding region 18 so as to realize transmission of a communication signal between the antenna 17 and the antenna IC 22. As an example, the antenna 17 is disposed on the first side 25a, i.e., the at least one antenna 17 is arranged adjacent to the first side 25a. The first bonding region 18 is disposed on the third side 25b, i.e., the first bonding region 18 is arranged adjacent to the third side 25b. In the surrounding-screen display terminal (i.e., the display terminal 300 in FIG. 1c), the display screen 100 is bent to be U-shaped. The at least one antenna 17 is disposed on a back side of the surrounding-screen display terminal, i.e., a rear antenna design is adopted. The take-up circuit region 27, the first bonding region 18 and the first flexible circuit board 19 are disposed on a front side of the surrounding-screen display terminal, and are folded on a back side of the display screen 100.

The surrounding-screen display terminal further includes a supporting rear housing 200 disposed between the first side 25a and the third side 25b and arranged at a surrounding opening of the display screen 100 that is curved around. The supporting rear housing 200 is configured to support and fix the display screen 100 and other components (e.g., a camera). As an example, the number of the antenna 17 is not limited, for example, there may be one or two. In the case that the display screen includes two antennas 17, both of the antennas 17 are disposed on the first side 25b and are arranged adjacent to the first side 25a. One antenna 17 is arranged proximal to the second side 25c, and the other antenna 17 is arranged proximal to the fourth side 25d. The two antennas 17 are connected to the first bonding region 18 by the edge wiring region 23.

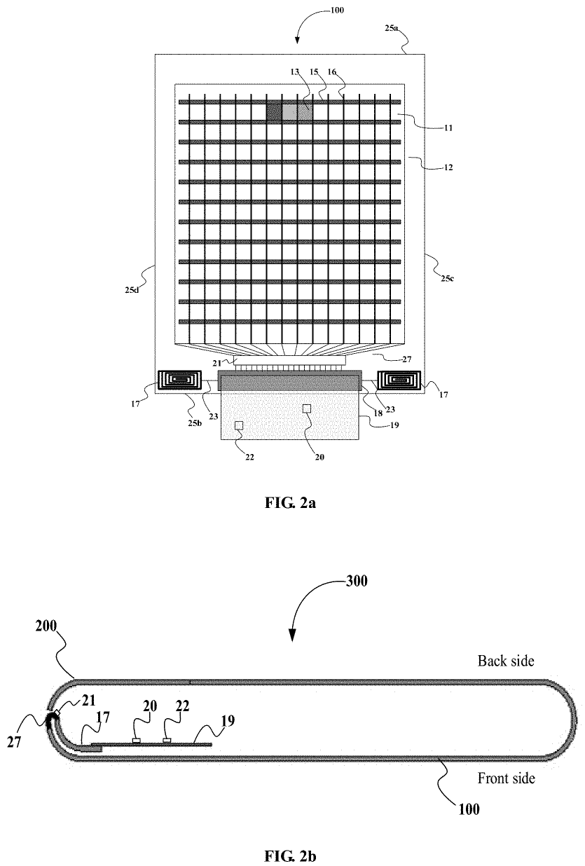

In some embodiments, the display screen 100 is a touch display screen and the screen driving IC 20 is a touch driving IC. As shown in FIGS. 2a and 2b, the non-display region 12 further includes a display driving IC 21 disposed between the take-up circuit region 27 and the first flexible circuit board 19; and in addition to the touch driving IC, an antenna IC 22 is bonded to the first flexible circuit board 19. The at least one antenna 17 is connected to the antenna IC 22 by wiring and the first bonding region 18 in the non-display region 12 sequentially.

In some embodiments, both of the antenna 17 and the first bonding region 18 are disposed on the third side 25b, i.e., both of the at least one antenna 17 and the first bonding region 18 are arranged adjacent to the third side 25b. The display screen 100 is applied to the surrounding-screen display terminal (i.e., the display terminal 300 in FIG. 2b). The at least one antenna 17, the take-up circuit region 27, the first bonding region 18 and the first flexible circuit board 19 are disposed on the front side of the surrounding-screen display terminal, and are folded on the back side of the display screen 100, i.e., a front antenna design is adopted.

The supporting rear housing 200 of the surrounding-screen display terminal is also disposed between the first side 25a and the third side 25b and is arranged at the surrounding opening of the display screen 100 that is curved around. The number of the antennas 17 is not limited, for example, there may be one or two. In the case that the number of the antennas 17 is two, as shown in FIG. 2a, both of the antennas 17 are disposed on the first side 25b, i.e., the two antennas 17 and the first bonding region 18 are both arranged adjacent to the third side 25b, and the first bonding region 18 is disposed between the two antennas 17. One antenna 17 is arranged proximal to the second side 25c, and the other antenna 17 is arranged proximal to the fourth side 25d.

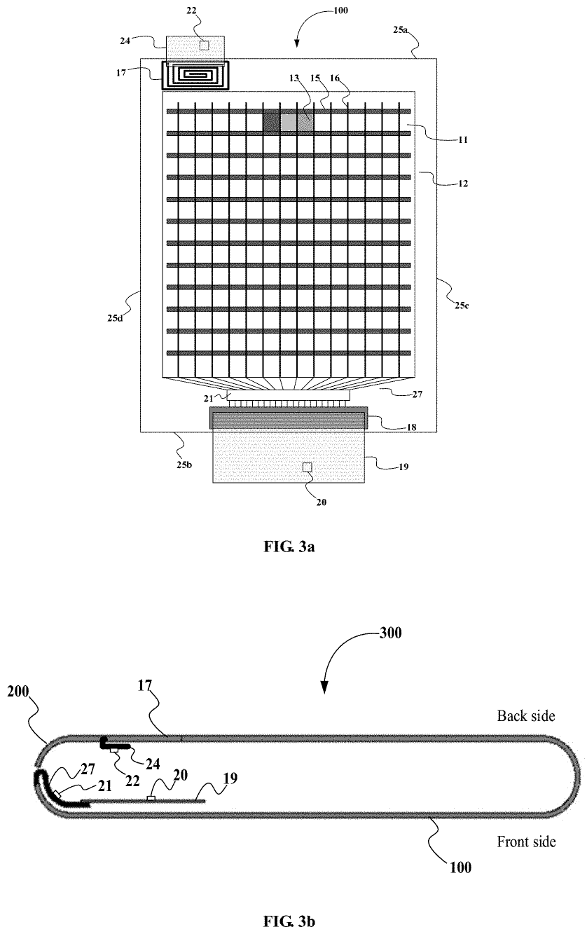

In some embodiments, the display screen 100 is a touch display screen, and the screen driving IC 20 is a touch driving IC. As shown in FIGS. 3a and 3b, the display screen further includes at least one second flexible circuit board 24 bonded to at least one antenna 17. The non-display region 12 further includes a display driving IC 21 disposed between the take-up circuit region 27 and the first flexible circuit board 19, and a second flexible circuit board 24 correspondingly bonded to each antenna 17, wherein an antenna IC 22 is bonded to the second flexible circuit board 24.

With this design, the antenna 17 is directly connected, without passing through the edge wiring region, to the second flexible circuit board 24 to which the antenna IC 22 is bonded, such that the structure of the edge wiring region can be simplified and the difficulty of an impedance matching design in a circuit can be reduced. In an embodiment of the present disclosure, at least one antenna 1 is disposed on and is arranged adjacent to the first side 25a. The first bonding region 18 is disposed on the third side 25b and is arranged adjacent to the third side 25b. The display screen 100 is applied to the surrounding-screen display terminal (i.e., the display terminal 300 in FIG. 3b), and the at least one antenna 17 is disposed on the back side of the surrounding-screen display terminal, i.e., a rear antenna design is adopted. The take-up circuit region 27, the first bonding region 18 and the first flexible circuit board 19 are disposed on the front side of the surrounding-screen display terminal, and are folded on the back side of the display screen 100.

The at least one second flexible circuit board 24 may be folded on the back side of the display screen 100 according to design requirements on a width of the non-display region on the back side of the surrounding-screen display terminal. In the case that the width of the non-display region on the back side of the surrounding-screen display terminal is large enough, the second flexible circuit board 24 may not be folded, either.

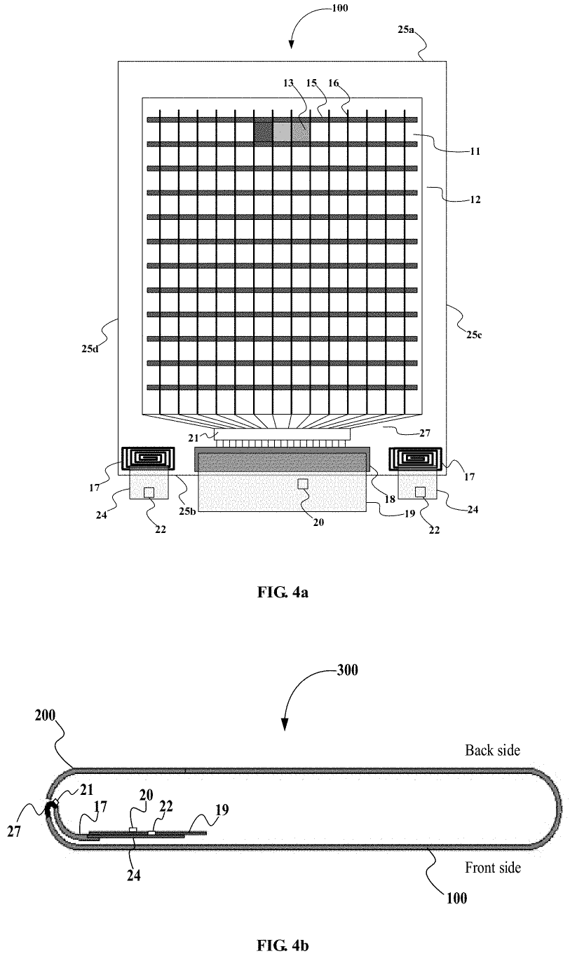

In some embodiments, the display screen 100 is a touch display screen and the screen driving IC 20 is a touch driving IC. As shown in FIGS. 4a and 4b, the non-display region 12 further includes a display driving IC 21 disposed between the take-up circuit region 27 and the first flexible circuit board 19, and a second flexible circuit board 24 correspondingly bonded to each antenna 17. An antenna IC 22 is bonded to the second flexible circuit board 24.

In some embodiments, the antenna 17 is disposed on the third side 25b, i.e., both of the at least one antenna 17 and the first bonding region 18 are arranged adjacent to the third side 25b. In the surrounding-screen display terminal (i.e., the display terminal 300 in FIG. 4b), the display screen 100 is bent to be U-shaped. The at least one antenna 17, the at least one second flexible circuit board 24, the take-up circuit region 27, the first bonding region 18 and the first flexible circuit board 19 are disposed on the front side of the surrounding-screen display terminal, and folded on the back side of the display screen 100, i.e., a front antenna design is adopted.

Where two antennas 17 are configured, as shown in FIG. 4a, the two antennas 17 and the first bonding region 18 are all arranged adjacent to the third side 25b, and the first bonding region 18 is disposed between the two antennas 17.

As shown in FIG. 5, such functional devices as IC are bonded to the first flexible circuit board 19 and the second flexible circuit board 24, and these functional devices are not bendable, such that a flexible circuit board may be divided into a flexible portion 26a and an inflexible part 26b. Taking the first flexible circuit board 19 as an example, the flexible portion 26a of the first flexible circuit board 19 is bonded to the first bonding region 18, and a screen driving IC 20 is bonded to the inflexible portion 26b of the first flexible circuit board 19. Similarly, the second flexible circuit board 24 may also be divided into a flexible portion 26a and an inflexible portion 26b. The flexible portion 26a of the second flexible circuit board 24 is bonded to the antenna 17, and an antenna IC 22 is bonded to the inflexible portion 26b of the second flexible circuit board 24.

In view of the bendability of the flexible circuit board, during design of the first flexible circuit board 19 and the second flexible circuit board 24, taking the first flexible circuit board 19 as an example, a width B of the flexible portion 26a, a bonding width L of the flexible portion 26a a width C of the inflexible portion 26b, and a bending radius R of the flexible portion 26a meet: B−C≥L+πR. To meet design requirements on these parameters, a folding process can be completed as long as a gap A of the display screen 100 curved around allows a suction nozzle that adsorbs the flexible portion 26a to be extended therein.

According to the display screen 100 in some embodiments, at least one antenna 17 is integrated in the non-display region 12 and is disposed in the same layer as at least one metal layer of the pixel circuit of the sub-pixel 13. In the case that the display screen 100 is applied to the display terminal 300, it is unnecessary to additionally provide and assemble an antenna module for the display terminal, which, compared with the related art, can reduce the assembling difficulty and the manufacturing cost of a whole device. In addition, the antenna 17 is designed in the non-display region 12 of the display screen 100, such that the area of the non-display region can be fully utilized. The number and positions of the antennas 17 can be flexibly designed as required, and hence the range of applicable products is wider. Moreover, the design of the display screen 100 is especially suitable for surrounding-screen display terminal products. In addition to the surrounding-screen display terminals, the display screen 100 may also be applicable to other curved display terminals or flat display terminals to achieve similar benefits as mentioned above.

Referring to FIG. 1c, an embodiment of the present disclosure further provides a display terminal 300. The display terminal 300 includes a display screen. The display screen includes a display region 11 and a non-display region 12 surrounding the display region 11. The display region 11 includes a plurality of sub-pixels 13. At least one of the plurality of sub-pixels 13 includes a pixel circuit and a light-emitting element 14. The pixel circuit is configured to drive the light-emitting element 14 and includes at least one metal layer. The non-display region 12 includes at least one antenna 17 disposed in the same layer as one of the at least one metal layer. The display screen in the display terminal 300 may be any of the display screens 100 described above. As stated above, compared with the related art, it is unnecessary to provide and assemble an antenna module for the display terminal, such that the assembling difficulty and the manufacturing cost of a whole device are greatly reduced.

As shown in FIG. 1c, the display terminal 300 is a surrounding-screen display terminal, and the display screen 100 is a flexible display screen that is curved around. The surrounding-screen display terminal further includes a supporting rear housing 200 disposed at a surrounding opening of the display screen 100.

Referring to FIG. 1a illustrating the structure of the display screen, the display screen 100 includes a first side 25a, a second side 25c, a third side 25b, and a fourth side 25d that are successively connected. The second side 25c and the fourth side 25d are curved, e.g., substantially bent to be C-shaped. The non-display region 12 further includes a take-up circuit region 27, a first bonding region 18 disposed on a side, distal from the display region 11, of the take-up circuit region 27, and a first flexible circuit board 19 bonded to the first bonding region 18, wherein a screen driving IC 20 is bonded to the first flexible circuit board 19.

As shown in FIGS. 1a and 1c, an antenna 17 is disposed on the first side 25a, i.e., the at least one antenna 17 is arranged adjacent to the first side 25a. The first bonding region 18 is disposed on the third side 25b, i.e., the first bonding region 18 is arranged adjacent to the third side 25b, and the at least one antenna 17 is disposed on a back side of the display terminal 300. The take-up circuit region 27, the first bonding region 18 and the first flexible circuit board 19 are disposed on a front side of the display terminal 300 and are folded on a back side of the display screen 100. As shown in FIGS. 2a and 2b, in another example, both of the antenna 17 and the first bonding region 18 are disposed on the third side 25b, i.e., the at least one antenna 17 and the first bonding region 18 are arranged adjacent to the third side 25b, and the at least one antenna 17, the take-up circuit region 27, the first bonding region 18 and the first flexible circuit board 19 are disposed on the front side of the display terminal 300 and are folded on the back side of the display screen 100.

In front antenna design, signal through holes may be designed in metal parts (not shown in the figure) in the display terminal 300 opposite to the antenna 17, such as some copper foil layers, to reduce shielding of signals and to improve the signal transmitting and receiving performance of the antenna 17.

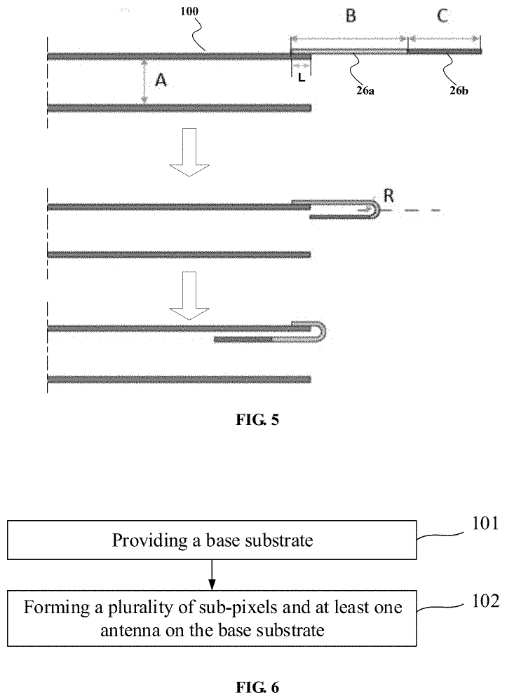

An embodiment of the present disclosure further provides a method for manufacturing a display screen. The display screen includes a display region 11 and a non-display region 12 surrounding the display region 11. The method is used for manufacturing any of the display screens described above. As shown in FIG. 6, the method includes the following processes.

In 101, abase substrate 601 is provided.

In 102, a plurality of sub-pixels 13 and at least one antenna 17 are formed on the base substrate.

The plurality of sub-pixels 13 are disposed in the display region 11, and the at least one antenna 17 is disposed in the non-display region 12. At least one of the plurality of sub-pixels 13 includes a pixel circuit and a light-emitting element 14. The pixel circuit is configured to drive the light-emitting element 14 and includes at least one metal layer. The at least one antenna 17 is manufactured in the same layer as one of the at least one metal layer.

Referring to FIG. 1b, the display screen includes a base substrate 601, a buffer layer 602, an active layer 603, a first insulating layer 604, a gate 605, a second insulating layer 607, a second electrode plate 608, a third insulating layer 609, a source 610, a passivation layer 612, a planarization layer 613, an anode layer 614, a pixel defining layer 615, a spacer layer 616, an organic light-emitting layer 617, a cathode layer 618, a first inorganic encapsulation layer 619, an organic encapsulation layer 620, and a second inorganic encapsulation layer 621 that are disposed on one side of the base substrate 601 and sequentially disposed in a direction going away from the base substrate 601; and the display screen further includes a first electrode plate 606 disposed in the same layer as the gate 605 and a drain 611 disposed in the same layer as the source 610. The antenna 17 may be disposed in the same layer as the gate 605, or the source 610 and the drain 611, or the first electrode plate 606 or the second electrode plate 608. In this display screen, for the specific manufacturing process of the above structures, reference may be made to the technological process in the related art.

It should be noted that, relation terms such as “first” and “second” are used herein merely to distinguish a subject or an operation from another subject or another operation, and not to imply any substantial relation or order between these subjects or operations. Moreover, the terms “include,” “contain,” and any variation thereof are intended to cover a nonexclusive containing meaning, such that a process, a method, an item or a device containing a series of elements not only includes these elements, but also includes other elements that are not set forth specifically, or also includes an inherent element of such a process, method, item or device. Without more limitations, the element defined by the phrase “including a . . . ” does not exclude the presence of additional equivalent elements in the process, method, item, or device that includes the element.

The various embodiments in the description are described in a related manner, the same or similar parts between the various embodiments may be referred to each other, and each embodiment focuses on the differences from the other embodiments.

Described above are merely optional embodiments of the present disclosure, and are not intended to limit the protection scope of the present disclosure. Within the spirit and principles of the present disclosure, any modifications, equivalent substitutions, improvements, and the like shall fall within the protection scope of the present disclosure.

What is claimed is:

1. A display screen, comprising a display region and a non-display region surrounding the display region; wherein
the display region comprises a plurality of sub-pixels, at least one of the plurality of sub-pixels comprising a pixel circuit and a light-emitting element, the pixel circuit being configured to drive the light-emitting element and comprising at least one metal layer; and
the non-display region comprises at least one antenna disposed in the same layer as one of the at least one metal layer.

2. The display screen according to claim 1, wherein the pixel circuit further comprises:
a drive transistor comprising an active layer, a gate, a source, and a drain, wherein the gate is disposed on a side of the active layer and is insulated from the active layer, and both of the source and the drain are disposed on a side, distal from the active layer, of the gate and are connected to the active layer; and
a storage capacitor comprising a first electrode plate and a second electrode plate, wherein the second electrode plate is disposed on a side, distal from the active layer, of the first electrode plate,
wherein the at least one antenna is disposed in the same layer as one of the gate, the source, the drain, the first electrode plate, and the second electrode plate.

3. The display screen according to claim 2, wherein one of the first electrode plate and the second electrode plate is disposed in the same layer as the gate.

4. The display screen according to claim 2, wherein one of the first electrode plate and the second electrode plate is disposed in the same layer as the source.

5. The display screen according to claim 1, wherein
the non-display region further comprises a take-up circuit region, a first bonding region, and a first flexible circuit board, wherein the first bonding region is disposed on a side, distal from the display region, of the take-up circuit region, the first flexible circuit board is bonded to the first bonding region, and a screen driving integrated circuit is bonded to the first flexible circuit board.

6. The display screen according to claim 5, wherein
an antenna integrated circuit is further bonded to the first flexible circuit board, and the at least one antenna is connected to the antenna integrated circuit by wiring and the first bonding region in the non-display region sequentially.

7. The display screen according to claim 5, further comprising at least one second flexible circuit board, wherein
the second flexible circuit board is bonded to the at least one antenna, and an antenna integrated circuit is bonded to the second flexible circuit board.

8. The display screen according to claim 7, wherein
each of the first flexible circuit board and the second flexible circuit board comprises a flexible portion and an inflexible portion, wherein a width B of the flexible portion, a bonding width L of the flexible portion, a width C of the inflexible portion, and a bending radius R of the flexible portion meet: B−C≥L+πR.

9. The display screen according to claim 5, wherein the display screen is a flexible display screen and comprises a first side, a second side, a third side, and a fourth side that are successively connected; wherein the second side and the fourth side are curved, the first bonding region is disposed on the third side, and an antenna is disposed on at least one of:
the first side; or
the third side.

10. The display screen according to claim 9, wherein
two antennas are configured and are both disposed on the third side, wherein the first bonding region is disposed between the two antennas.

11. The display screen according to claim 9, wherein two antennas are configured and are both disposed on the first side, wherein one of the antennas is proximal to the second side, and the other of the antennas is proximal to the fourth side.

12. The display screen according to claim 1, wherein the at least one antenna comprises:
an annular coiled antenna; or
a rectangular coiled antenna.

13. The display screen according to claim 5, wherein
the display screen is a touch display screen, the screen driving integrated circuit is a touch driving integrated circuit, and the non-display region further comprises a display driving integrated circuit disposed between the take-up circuit region and the first flexible circuit board.

14. A display terminal, comprising a display screen, wherein the display screen comprises a display region and a non-display region surrounding the display region; wherein the display region comprises a plurality of sub-pixels, at least one of the plurality of sub-pixels comprising a pixel circuit and a light-emitting element, the pixel circuit being configured to drive the light-emitting element and comprising at least one metal layer; and the non-display region comprises at least one antenna disposed in the same layer as one of the at least one metal layer.

15. The display terminal according to claim 14, wherein the display terminal is a surrounding-screen display terminal; wherein the display screen is a flexible display screen, is curved around, and comprises a first side, a second side, a third side, and a fourth side that are successively connected, wherein the second side and the fourth side are bent to be U-shaped.

16. The display terminal according to claim 15, wherein the surrounding-screen display terminal further comprises a supporting rear housing disposed between the first side and the third side.

17. The display terminal according to claim 15, wherein the non-display region further comprises a take-up circuit region, a first bonding region and a first flexible circuit board;
wherein the first bonding region is disposed on a side, distal from the display region, of the take-up circuit region, and the first flexible circuit board is bonded to the first bonding region, a screen driving integrated circuit being bonded to the first flexible circuit board.

18. The display terminal according to claim 16, wherein
at least one antenna is disposed on the first side;
a first bonding region is disposed on the third side;
the at least one antenna is disposed on a back side of the surrounding-screen display terminal; and
a take-up circuit region, the first bonding region, and a first flexible circuit board are disposed on a front side of the surrounding-screen display terminal and are folded on a back side of the display screen.

19. The display terminal according to claim 16, wherein
both of the at least one antenna and a first bonding region are disposed on the third side, and the at least one antenna, a take-up circuit region, the first bonding region, and a first flexible circuit board are disposed on a front side of the surrounding-screen display terminal and are folded on a back side of the display screen; and
a metal part of the surrounding-screen display terminal opposite to the at least one antenna is provided with a signal through hole.

20. A method for manufacturing a display screen, wherein the display screen comprises a display region and a non-display region surrounding the display region, comprising:
providing a base substrate; and
forming a plurality of sub-pixels and at least one antenna on the base substrate; wherein the plurality of sub-pixels are disposed in the display region; the at least one antenna is disposed in the non-display region; at least one of the plurality of sub-pixels comprises a pixel circuit and a light-emitting element, the pixel circuit being configured to drive the light-emitting element and comprising at least one metal layer; and the at least one antenna is manufactured in the same layer as one of the at least one metal layer.
